(19) United States
(12) Patent Application Publication
(10) Pub. No.: US 2026/0179709 A1
(43) Pub. Date: Jun. 25, 2026

(54) Memory with Enhanced Design-for-Test Bypass Mode

(71) Applicant: QUALCOMM Incorporated, San Diego, CA (US)

(72) Inventors: Sumeer GOEL, Austin, TX (US); Peter Normand LABRECQUE, Austin, TX (US); Maciej BAJKOWSKI, Austin, TX (US); Samer GHANEM, Austin, TX (US); Sai Prakash Reddy BIJIVEMULA, Leander, TX (US)

(21) Appl. No.: 18/988,773

(22) Filed: Dec. 19, 2024

(51) Int. Cl. G11C 29/14; G11C 29/12; G11C 29/32

(52) U.S. Cl. CPC G11C 29/14; G11C 29/1201; G11C 29/32; G11C 2029/3202

(57) ABSTRACT

A memory is provided with a read data latch that latches a read data signal during a read operation to the memory responsive to a first binary value of a bypass signal. During a design-for-test bypass mode for the memory, a write data latch latches a data in signal from a scan chain to provide a write data signal. The read data latch responds to a second binary value of the bypass signal by latching the write data signal.

### TECHNICAL FIELD

This application relates to integrated circuits, and more particularly to an integrated circuit embedded memory with enhanced an enhanced design-for-test bypass mode.

### BACKGROUND

An integrated circuit such as a system-on-a-chip (SoC) may include thousands of embedded memories. A majority of the semiconductor die used to form the SoC is then occupied by the embedded memories. The power consumption and operating speed of the embedded memories may thus be vital to a successful performance of the SoC. A remaining core of the SoC is typically formed using assorted logic circuits (collections of logic gates) and storage elements (for example, flip-flops). Given the differences between the embedded memories and the SoC core, different test techniques have been developed to verify proper operation of the SoC. For example, various memory built-in-self-test (MBIST) architectures have been developed to test the embedded memories. In contrast, the SoC core is typically tested using automatic test pattern generation (ATPG) techniques in a design-for-test (DFT) procedure. During an ATPG procedure, the flip-flops in the SoC core are organized into scan chains. Test patterns may then be shifted into the scan chains followed by a capture procedure so that output test patterns may then be shifted out of the scan chains and compared to the expected values to verify proper operation. The embedded memories include write data latches that are included in the scan chains. But since the ATPG is not testing the embedded memories, the scan chains bypass the bitcell array and associated memory periphery (e.g., address decoders, write drivers, row decoders, and sense amplifiers) is what is denoted as a DFT bypass mode.

Although the DFT bypass mode advantageously allows a manufacturer to verify the proper operation of the logic circuits scanned by the scan chains, the inclusion of the write data latch in a scan chain typically slows the read data critical path (from a read data latch to a data output signal).

### SUMMARY

In accordance with an aspect of the disclosure, a memory is provided that includes: a write data latch configured to latch a data in signal during a design-for-test bypass mode for the memory to provide a write data signal; and a read data latch configured to latch a read data signal through a first input terminal during a read operation to the memory and to latch the write data signal through a second input terminal during the design-for-test bypass mode.

In accordance with another aspect of the disclosure, a method of operation for a memory is provided that includes: processing a read data signal through a first logic gate in a read data latch to provide a latched output signal at an output terminal of the first logic gate responsive to a first binary value of a bypass signal during a read operation to the memory; latching a data in signal from a scan chain in a write data latch during a design-for-test bypass mode for the memory to provide a write data signal; and latching the write data signal in the read data latch responsive to a second binary value of the bypass signal during the design-for-test bypass mode for the memory.

In accordance with yet another aspect of the disclosure, a memory is provided that includes: a write data latch; a read data latch including a first logic gate having an input terminal for receiving a read data signal and having an output terminal for providing an output signal from the read data latch; and a second logic gate configured to process a write data signal from the write data latch with a bypass signal for a design-for-test bypass mode for the memory, wherein the read data latch includes a third logic gate including an input terminal coupled to an output terminal of the second logic gate.

These and other advantageous features may be better appreciated through the following detailed description.

### BRIEF DESCRIPTION OF THE DRAWINGS

FIG. 1 illustrates a traditional memory that implements a DFT bypass mode using a bypass multiplexer in a critical path of the memory.

FIG. 2 illustrates a traditional memory that implements a DFT bypass mode using a bypass logic circuit in a critical path of the memory.

FIG. 3 illustrates a first implementation of a memory having an improved DFT bypass mode in which the read latch is modified to implement the DFT bypass mode without the use of an additional bypass multiplexer or a bypass logic circuit in accordance with an aspect of the disclosure.

FIG. 4 illustrates a second implementation of a memory having an improved DFT bypass mode in which the read latch is modified to implement the DFT bypass mode without the use of an additional bypass multiplexer or a bypass logic circuit in accordance with an aspect of the disclosure.

FIG. 5 illustrates a modification of the memory of FIG. 3 for an implementation in which the data input signal during the DFT bypass mode has a fixed binary value in accordance with an aspect of the disclosure.

FIG. 6 illustrates the scan chain in a memory having an improved DFT bypass mode in accordance with an aspect of the disclosure.

FIG. 7 is a flowchart of a method implementing a DFT bypass mode in accordance with an aspect of the disclosure.

FIG. 8 illustrates some example mobile devices including a memory having an improved DFT bypass mode in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

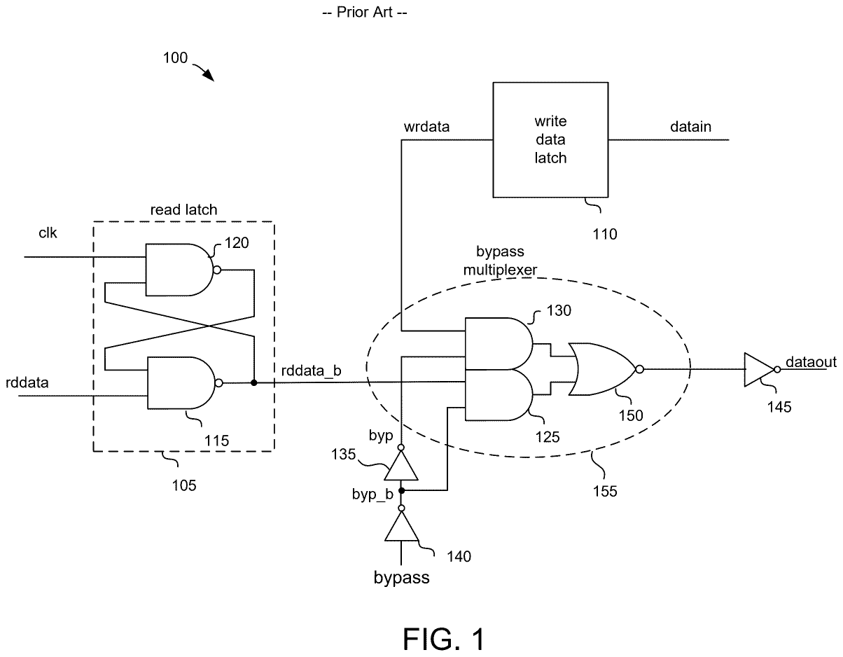

In a memory with a DFT bypass mode, logic is typically added either before or after the read data latch to multiplex between a write data signal from the write latch in the scan chain during ATPG testing and a read data bit from a read operation during normal operation. The resulting logic gates in the memory critical path undesirably slows the memory access speed. An example memory 100 with a traditional bypass multiplexer 155 is shown in FIG. 1. During a read operation, a read data (rddata) signal is latched by a read latch 105 responsive to cycles of a memory clock signal (clk). The read latch latches the read data signal using a pair of cross-coupled logic gates such as the cross-coupled NAND gates 115 and 120. The read data signal drives an input terminal of the NAND gate 115. Similarly, the memory clock signal drives an input terminal the NAND gate 120. An output terminal of the NAND gate 115 functions as the output terminal of the read latch 105 to provide a complement read data signal (rddata_b).

During a read operation to the memory 100, a bypass multiplexer 155 selects for the complement read data signal from the read latch 105 in response to a first binary value (e.g., a logic zero value) of a bypass signal for the DFT bypass mode. To perform this selection, an inverter 140 inverts the bypass signal to provide a complement bypass signal (byp_b). The complement bypass signal is thus asserted to a memory power supply voltage (a logic one value in an active-high convention) when the bypass signal is a logic zero value. The bypass multiplexer 155 includes an AND gate 125 that ANDs the complement read data signal with the complement bypass signal. The AND gate 125 will thus pass the read data output signal during a read operation. An inverter 135 inverts the complement bypass signal to produce a buffered bypass signal (byp) that is received by an AND gate 130. An output signal of the AND gate 130 will thus be a logic zero during a read operation. A NOR gate 150 NORs the output signals from the AND gates 125 and 130. During a read operation, the NOR gate 150 will thus pass a buffered version of the read data signal to an inverter 145 that inverts the buffered version of the read data signal to provide a data output signal (dataout).

To allow a scan in signal to pass through the bypass multiplexer 155 during a DFT bypass mode, a data in signal (datain) from a scan chain (not illustrated) is latched in a write data latch 110 to form a write data signal (wrdata). The write data signal is received by the AND gate 130. When the bypass signal is asserted, the AND gate 130 will pass the write data signal whereas the AND gate 125 will block the complement data output signal. The write data signal is then inverted by the NOR gate 150 and again inverted by the inverter 145 to provide the data output signal as a scan out signal during the DFT bypass mode.

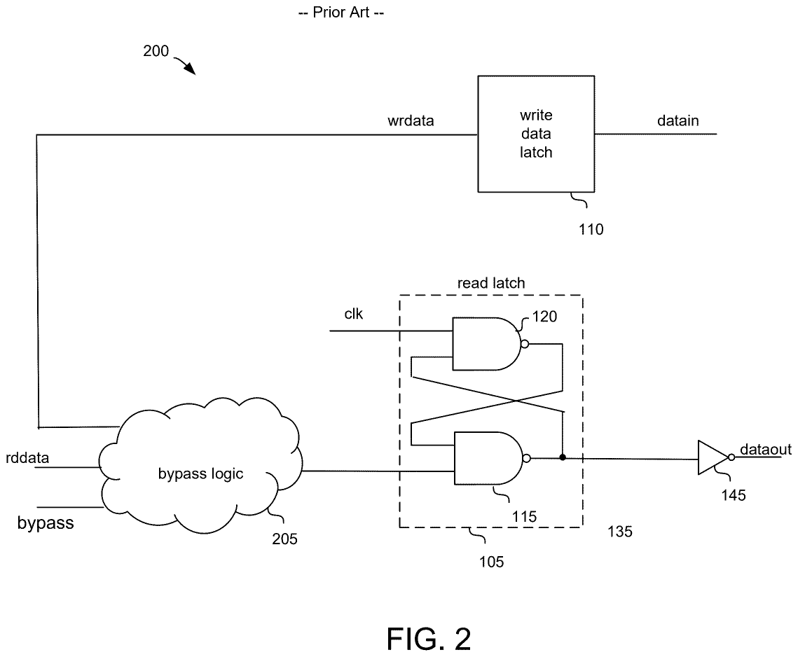

Although the bypass multiplexer 155 allows the read data signal to pass through the bypass multiplexer 155 during a read operation, note that the delay between a critical path from the production of the read data signal and the latching of the data output signal in a data output latch (not illustrated) is exacerbated or lengthened by the processing delay through the AND gate 125 and through the NOR gate 150 in the bypass multiplexer 155. This increased critical path delay undesirably slows the operating speed of the memory 100. As shown in FIG. 2 for a memory 200, rather than use a bypass multiplexer, bypass logic 205 may be used prior to the read latch 105. The bypass logic 205 selects for the write data signal from the write latch 110 during a DFT bypass mode in response to an assertion of the bypass signal. During a read operation, the bypass signal is de-asserted, which causes the bypass logic 205 to select for the read data signal. A selected signal from the bypass logic 205 is latched in the read latch 105 and inverted by the inverter 145 to form the data output signal. But the bypass logic 205 is inserted within the critical path for the memory 200, which undesirably slows the operating speed of the memory 200.

An advantageous memory is provided that provides a DFT bypass mode yet does not appreciably affect the critical path delay during a read operation. To provide a better appreciation of this innovation, consider again the latching within the read data latch 105 for memories 100 or 200 during a read operation. The memory clock signal is de-asserted (grounded) in one-half of each memory clock cycle. During the de-assertion of the memory clock signal, the output signal from the NAND gate 120 is a binary one. Should the read data signal be a binary one during this de-assertion of the memory clock signal, the complement read data signal will be a binary zero. The binary zero state of the complement read data signal causes the output signal of the NAND gate 120 to remain as a binary one even when the memory clock signal is again asserted in the subsequent memory clock cycle. Should the read data signal have a falling edge in the (a transition from the memory power supply voltage to ground) during the subsequent memory clock cycle, the complement read data signal will transition high in response to the falling edge of the read data signal.

Conversely, suppose that the complement read data signal is a binary one. The output signal of the NAND gate 120 will then be a binary zero while the memory clock signal is asserted. Should the read data signal have a rising edge (a transition from ground to the memory power supply voltage), the complement read data signal cannot change its binary state so long as the output signal from the NAND gate 120 is a binary zero. But at the falling edge of the memory clock signal, the output signal from the NAND gate 120 will transition to a binary one, which in combination with the now-high state of the read data signal causes the complement read data signal to transition to ground. It may thus be seen that the complement read data signal changes its binary state either in response to a falling edge of the read data signal or in response to a falling edge of the memory clock signal. In the memory disclosed herein, the read data latch is improved to implement the DFT bypass mode, yet it retains this functional behavior of the two cross-coupled NAND gates 115 and 120. An output signal from the modified read data latch may then be inverted to provide a data output signal without any significant impact to the critical path (the path from the latching of the read data output signal such as in a sense amplifier to the latching of the data output signal in a data output latch). In a first implementation of the improved read latch, a two-input logic gate (e.g., a NAND gate) receives the read data signal analogously as discussed for the read latch 105. In a second implementation of the improved read latch, a three-input logic gate (e.g., a three-input NAND gate) receives the read data signal. The first implementation of the improved read latch will now be discussed in more detail followed by a discussion of the second implementation.

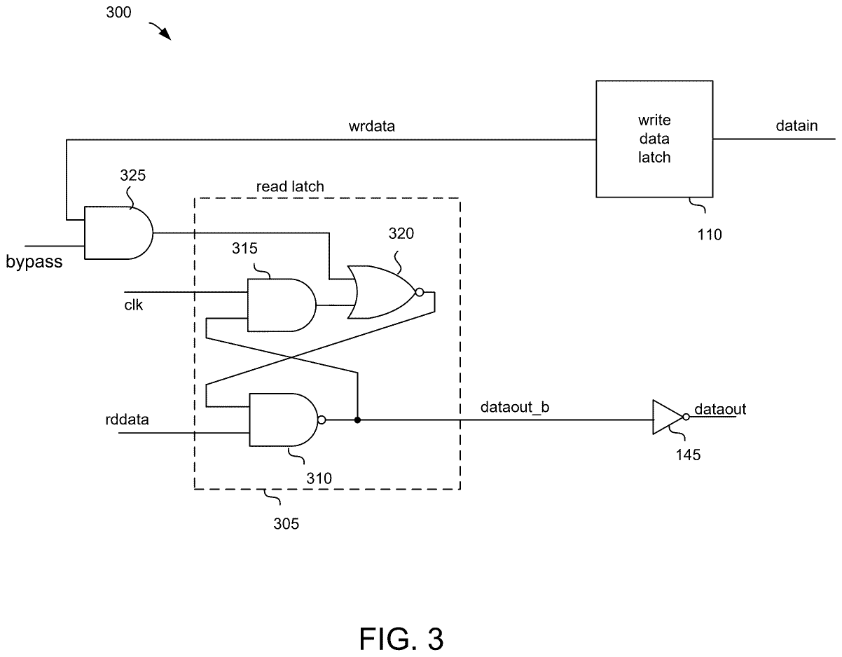

A memory 300 shown in FIG. 3 includes an improved read latch 305 that not only latches the read data signal during a read operation but also latches and selects for the write data signal during a DFT bypass mode. Since no separate bypass multiplexer or bypass logic is then needed, the critical path delay for the memory 300 is substantially unaffected as compared to a memory that does not offer a DFT bypass mode. In the read latch 305, a first logic gate such as a first NAND gate 310 receives the read data signal (rddata). A first AND gate 325 ANDs the bypass signal with the write data signal (wrdata) from the write data latch 110. The AND gate 325 is also denoted herein as a second logic gate. As discussed for the memories 100 and 200, the write data latch 110 latches a data input signal (datain) from a scan chain (not shown in FIG. 3 but discussed further herein) during the DFT bypass mode. The write data latch 110 also latches the data input signal during a write operation, but the write path from the write data latch to the corresponding write driver for the memory 300 is not shown in FIG. 3 for illustration clarity. The memory clock signal is received by a second AND gate 315 that also receives a complement data output signal (dataout_b) as produced by the NAND gate 310. A NOR gate 320 NORs the output signals from the AND gates 325 and 315 to produce an output signal that is NANDed by the NAND gate 310 with the read data signal to produce the complement data output signal. The NOR gate 320 is also denoted herein as a third logic gate.

During a read operation, the bypass signal is a binary zero, which forces the output signal of the AND gate 325 to also be a binary zero. Suppose that the complement data output signal is a binary one prior to a rising edge of the read data signal. While the clock signal is high (asserted to the memory power supply voltage), the output signal from the AND gate 315 will be a binary one, which forces the output signal from the NOR gate 320 to be a binary zero. In turn, the binary zero from the output signal of the NOR gate 320 prevents the NAND gate 310 from reacting to a rising edge of the read data signal. The complement data output signal thus cannot react to the rising edge of the read data signal until a subsequent falling edge of the memory clock signal. At the falling edge of the memory clock signal, the NOR gate 320 will NOR two binary zeroes, which causes the NOR gate 320 to assert its output signal. At this assertion of the output signal from the NOR gate 320, the NAND gate 310 will be NANDing two binary ones, which causes the NAND gate 320 to de-assert the complement data output signal. The complement data output signal thus does not have a falling edge in response to the rising edge of the read data signal until the memory clock signal has a falling edge. This is the same functional behavior of the read latch 105 discussed with respect to memory 100 yet there is no delay from a bypass multiplexer nor is there a delay from a bypass logic. The inverter 145 inverts the complement data output signal to provide the data output signal (dataout). The inverter 145 is also denoted herein as a first inverter.

Should instead the complement data output signal be a binary zero prior to a falling edge of the read data signal during a read operation, the memory clock signal is blocked by the AND gate 315. The output signal of the AND gate 315 will thus be a binary zero regardless of whether the memory clock signal is high or low. The output signal of the NOR gate 320 will thus be a binary one since it will be NORing two binary zeroes. At the falling edge of the read data signal, the complement data output signal transitions from a binary zero to a binary one because of the resulting binary zero input of the read data signal to the NAND gate 310. The complement data output signal will thus not have a rising edge until the read data signal has a falling edge, which is the same functional behavior as discussed with respect to the read latch 105 yet there is no delay from a bypass multiplexer nor is there a delay from a bypass logic. During a read operation, the read data latch 305 latches the read data signal through a first input terminal (the corresponding input terminal to the NAND gate 310). Similarly, during the DFT bypass mode, the read data latch 305 latches the write data signal through a second input terminal (the corresponding input terminal to the NOR gate 320).

In a DFT bypass mode for the memory 300, the bypass signal is asserted and the read data signal is pre-charged high. Should the memory clock signal be a binary zero and the data input signal is also a binary zero, the NOR gate 320 will be NORing two binary zeroes, which forces the output signal of the NOR gate 320 be a binary one. The NAND gate 310 will then be NANDing two binary ones, which forces the complement data output signal to be a binary zero. It then doesn't matter if the memory clock signal is subsequently asserted to a binary one because the output signal of the AND gate 315 is forced to be a binary zero by the binary zero value of the complement data output signal. Conversely, if the data input signal is a binary one during the DFT bypass mode, the output signal from the AND gate 325 will be a binary one, which forces the output of the NOR gate 320 to be a binary zero regardless of the binary value of the memory clock signal. The binary zero value of the output signal from the NOR gate 320 then forces the NAND gate 310 to discharge the complement data output signal to be a binary zero. Due to the inversion of the complement data output signal by the inverter 145, the data output signal is a binary one when the data input signal is a binary zero during the DFT bypass mode. Conversely, the data output signal is a binary zero when the data input signal is a binary one during the DFT bypass mode.

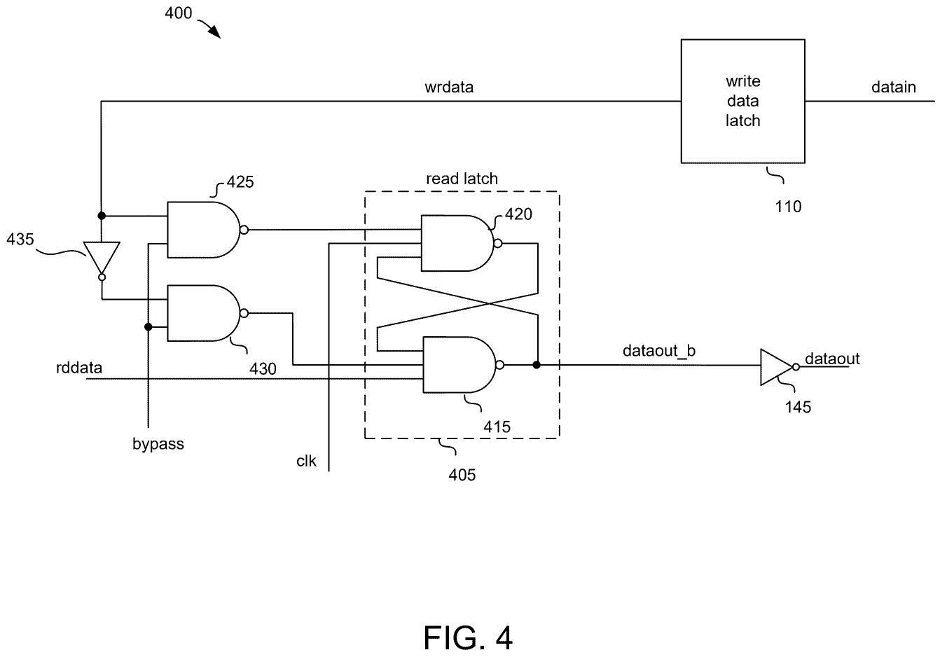

Turning now to FIG. 4, the second implementation will now be discussed with respect to a memory 400. An improved read latch 405 includes a pair of cross-coupled three-input logic gates such as a three-input first NAND gate 415 and a three-input second NAND gate 420. The NAND gate 420 is also denoted herein as a third logic gate. A two-input logic gate such as a third NAND gate 425 NANDs the bypass signal with the write data signal from the write data latch 110. An output signal from the NAND gate 425 that is received by the NAND gate 420 will thus be a logic one during the bypass mode. Similarly, a two-input logic gate such as a fourth NAND gate 430 NANDs the bypass signal with a complement of the write data signal as inverted by an inverted 435. An output signal from the NAND gate 430 that is received by the NAND gate 415 will thus be a logic one during the bypass mode.

The NAND gate 420 NANDs the output signal from the NAND gate 425 with the memory clock signal and with the complement data output signal (dataout_b) produced by the NAND gate 415. Suppose that the complement data output signal is a binary one during a read operation. The output signal from the NAND gate 420 will then be a binary zero since the NAND gate 420 will be NANDing three binary ones. The complement data output signal then cannot respond to a rising edge in the read data signal until the memory clock signal has a falling edge because the falling edge causes the output signal from the NAND gate 420 to be a binary one. The NAND gate 415 is then NANDing three binary ones, which causes the NAND gate 415 to discharge the complement data output signal to a binary zero. The complement data output signal thus does not have a falling edge in response to the rising edge of the read data signal until the memory clock signal has a falling edge. This is the same functional behavior of the read latch 105 discussed with respect to memory 100 yet there is no delay in the memory 400 from a bypass multiplexer nor is there a delay from a bypass logic. The inverter 145 inverts the complement data output signal to provide the data output signal (dataout).

Should instead the complement data output signal be a binary zero prior to a falling edge of the read data signal during a read operation, the memory clock signal will be blocked by the NAND gate 420 since the NAND gate 420 is NANDing the binary zero from the complement data output signal, which forces the NAND gate 420 to assert its output signal to a binary one. Prior to the falling edge of the read data signal, the NAND gate 415 is NANDing three binary zeroes, which forces the NAND gate 415 to maintain the complement data output signal as a binary zero. At the falling edge of the read data signal, the NAND gate 415 asserts the complement data output signal. The complement data output signal in the memory 400 will thus not have a rising edge until the read data signal has a falling edge, which is the same functional behavior as discussed with respect to the read latch 105 yet there is no delay from a bypass multiplexer nor is there a delay from a bypass logic. During a read operation, the read data latch 405 latches the read data signal through a first input terminal (the corresponding input terminal of the NAND gate 415). Similarly, during the DFT bypass mode, the read data latch 405 latches the write data signal through a second input terminal (the corresponding input terminal of the NAND gate 420).

During the DFT bypass mode, the bypass signal is asserted. Should the data input signal being latched in the write data latch 100 to form the write data signal be a binary one, the NAND gate 425 will then be NANDing two binary ones, which forces the output signal from the NAND gate 425 to be a binary zero. The inversion of the write data signal in the inverter 435 forces the output signal from the NAND gate 430 to be binary zero in response to the binary one value of the write data signal. The NAND gate 415 will then be NANDing three binary ones (recall that the read data signal is pre-charged to be a binary one during the DFT bypass mode). The NAND gate 415 will thus discharge the complement data output signal to be a binary zero in response to the binary one value of the data input signal. The data output signal is thus a binary one during the DFT bypass mode in response to a binary one value of the data input signal.

Should the data input signal be a binary zero during the DFT bypass mode, the output signal from the NAND gate 425 will be a binary one whereas the output signal from the NAND gate 430 will be a binary zero. The binary zero from the NAND gate 430 forces the NAND gate 415 to assert the complement data output signal to a binary one. The data output signal is thus a binary zero during the DFT bypass mode in response to a binary zero of the data output signal.

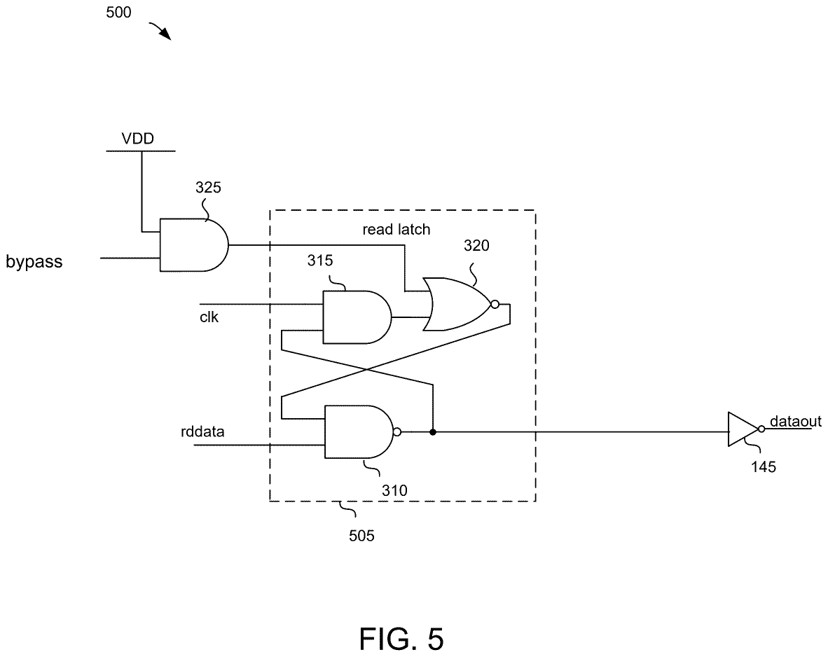

Numerous modifications may be made to the memories 300 and 400. For example, the NAND gates 415 and 420 in the memory 400 may instead be three-input NOR gates in an alternative implementation. Similarly, the NAND gate 310 of the memory 300 may instead be a NOR gate in an alternative implementation. In addition, there may be implementations in which the data input signal during the DFT bypass mode has a fixed binary value (a constant binary one or a constant binary zero). For example, memory 300 may be modified as shown for a memory 500 of FIG. 5. Read latch 305 is formed as discussed with respect to memory 300. But an AND gate 505 ANDs the bypass signal with the memory power supply voltage VDD since it is assumed that the data input signal from the scan chain will be a fixed binary one. The AND gate 505 replaces the AND gate 325 from the memory 300. Alternatively, the connection to the memory power supply voltage VDD at the input terminal of the AND gate 505 may be replaced with a connection to ground for an implementation in which it is assumed that the data input signal from the scan chain will be a fixed binary zero. Memory 400 may be modified accordingly, either for data input signal during the DFY bypass mode being fixed at a value of a binary one or of a binary zero.

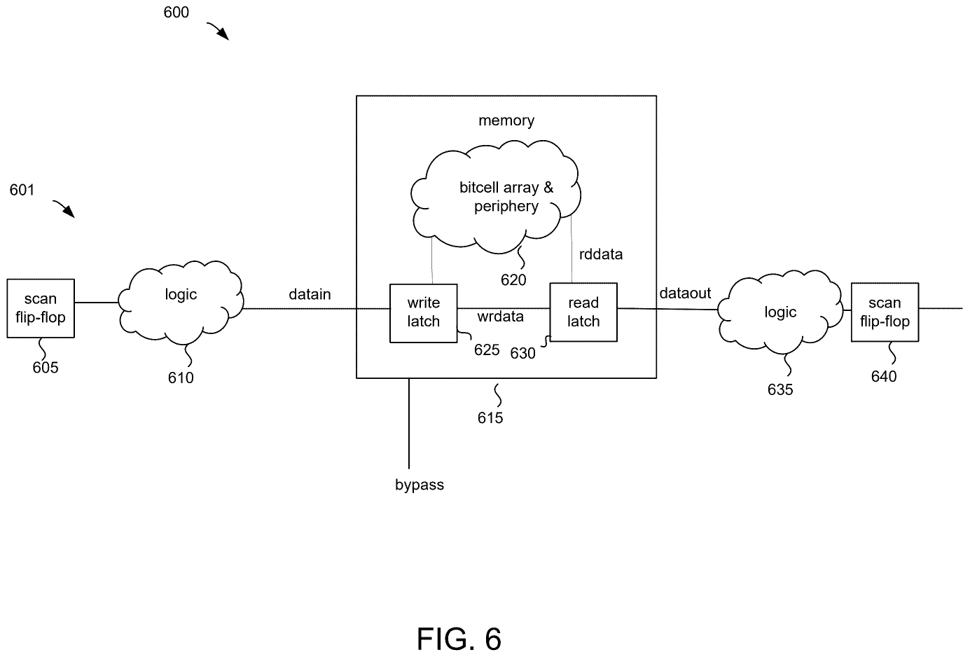

Regardless of whether the data input value during the DFT bypass mode is variable as discussed with respect to memories 300 and 400 or fixed such as discussed with regard to memory 500, the resulting DFT bypass mode does not appreciably impact the critical path delay during a read operation. A memory 600 with a DFT bypass mode is shown in FIG. 6 that is generic to the implementations disclosed herein. A scan chain 601 includes a clocked storage element such as a first flip-flop 605 that couples to a write latch 625 in a memory 615 through a first combination logic path 610. In a write operation, a write path (not illustrated) couples to the write latch 625 so that the write latch may store a write data signal that couples to a bitcell array and periphery 620 in the memory 615. As noted earlier, a memory periphery includes components such as address decoders, write drivers, row decoders, and sense amplifiers that support reading and writing to the bitcell array. In a write operation, the write data signal latched in the write latch 625 would couple through a write driver in the memory periphery to be written to a selected bitcell in the bitcell array.

In a DFT bypass mode, a data input signal from the scan chain 601 is latched in the write latch 625 to form the write data signal (wrdata) latched in the write latch 625. The write data signal is latched in a read latch 630 to form the data output signal (dataout) that then couples through a second combinational logic path 635 to be latched in a second flip-flop 630 in the scan chain 601. In a read operation, the read latch 630 latches the read data signal (rddata) from a sense amplifier in the bitcell array and periphery 620

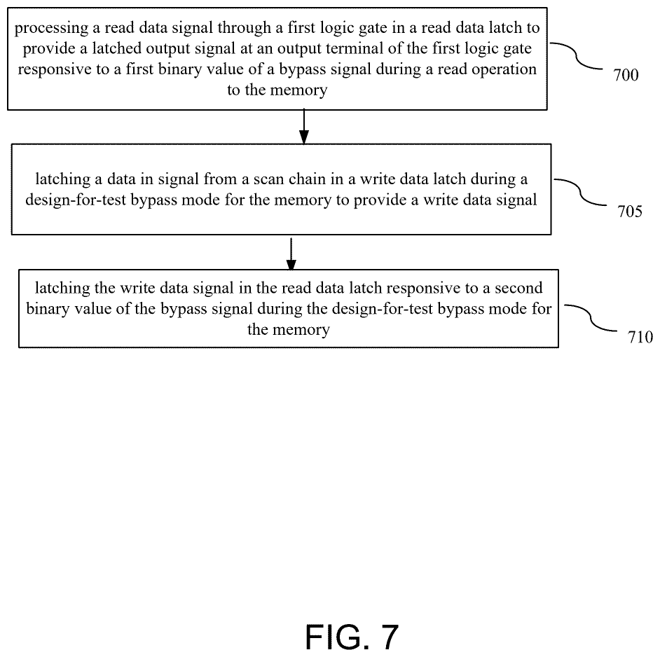

A method of operation for a memory with an improved DFT bypass mode will now be discussed with respect to the flowchart of FIG. 7. The method includes an act 700 of processing a read data signal through a first logic gate in a read data latch to provide a latched output signal at an output terminal of the first logic gate responsive to a first binary value of a bypass signal during a read operation to the memory. The processing of the read data signal through the read data latch 305 or 405 is an example of act 700. The method also includes an act 705 of latching a data in signal from a scan chain in a write data latch during a design-for-test bypass mode for the memory to provide a write data signal. The latching of the data in signal in the write data latch 110 in either of the memories 300 or 400 is an example of act 705. Finally, the method includes an act 710 of latching the write data signal in the read data latch responsive to a second binary value of the bypass signal during the design-for-test bypass mode for the memory. The latching of the write data signal in the read data latch 305 or 405 is an example of act 710.

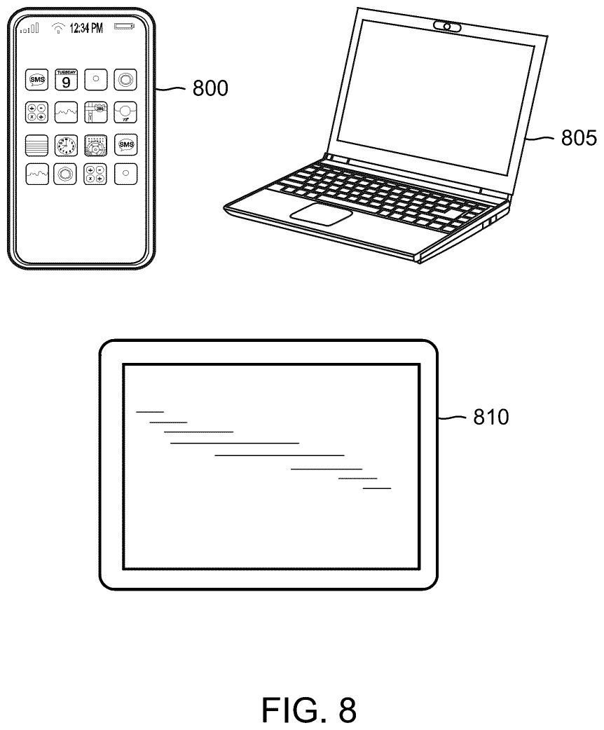

A memory having the improved DFT bypass mode as disclosed herein may be advantageously included in a variety of electronic systems. For example, as shown in FIG. 8, a cellular telephone 800, a laptop computer 805, and a tablet PC 810 may all include a memory having an improved DFT bypass mode in accordance with the disclosure. Other exemplary electronic systems such as a music player, a video player, a communication device, and a personal computer may also be configured with a memory in accordance with the disclosure.

The disclosure will now be summarized in the following series of clauses:

Clause 1. A memory, comprising:
a write data latch configured to latch a data in signal during a design-for-test bypass mode for the memory to provide a write data signal; and
a read data latch configured to latch a read data signal through a first input terminal during a read operation to the memory and to latch the write data signal through a second input terminal during the design-for-test bypass mode.

Clause 2. The memory of clause 1, further comprising:
a bitcell array; and
a memory periphery, wherein the memory periphery is configured to write the write data signal from the write data latch to the bitcell array during a write operation and to read the read data signal from the bitcell array during the read operation.

Clause 3. The memory of any of clauses 1-2, further comprising:
a first inverter configured to invert an output signal from the read data latch to provide a data output signal.

Clause 4. The memory of clause 3, wherein the read data latch comprises:
a first logic gate having an input terminal configured to receive the read data signal and having an output terminal configured to provide the output signal from the read data latch.

Clause 5. The memory of clause 4, wherein the first logic gate comprises a first NAND gate.

Clause 6. The memory of any of clauses 4-5, further comprising:
a scan chain including a first flip-flop coupled to an input terminal of the write data latch and including a second flip-flop coupled to an output terminal of the first inverter.

Clause 7. The memory of clause 6, wherein the first flip-flop is coupled to the input terminal of the write data latch through a first combinational logic path, and wherein the second flip-flop is coupled to the output terminal of the first inverter through a second combinational logic path.

Clause 8. The memory of clause 5, further comprising:
a first AND gate configured to AND the write data signal with a bypass signal for the design-for-test bypass mode; and
a NOR gate configured to NOR an output signal of the first AND gate, wherein the first NAND gate is configured to NAND the read data signal with an output signal from the NOR gate.

Clause 9. The memory of clause 8, further comprising:
a second AND gate configured to AND an output signal from the read data latch with a memory clock signal, wherein the NOR gate is further configured to NOR the output signal from the first AND gate with an output signal from the second AND gate.

Clause 10. The memory of clause 5, further comprising: a second NAND gate that is cross coupled with the first NAND gate.

Clause 11. The memory of clause 10, further comprising:
a third NAND gate configured to NAND a bypass signal for the design-for-test bypass mode with the write data signal, wherein the second NAND gate is a three-input NAND gate configured to NAND an output signal from the third NAND gate with a memory clock signal and with an output signal from the first NAND gate.

Clause 12. The memory of clause 11, further comprising:
a fourth NAND gate configured to NAND the bypass signal with an inverted version of the write data signal, wherein the first NAND gate is a three-input NAND gate configured to NAND an output signal from the second NAND gate with the read data signal and with an output signal from the fourth NAND gate.

Clause 13. The memory of any of clauses 1-12, wherein the memory is incorporated into a cellular telephone.

Clause 14. A method of operation for a memory, comprising:
processing a read data signal through a first logic gate in a read data latch to provide a latched output signal at an output terminal of the first logic gate responsive to a first binary value of a bypass signal during a read operation to the memory;
latching a data in signal from a scan chain in a write data latch during a design-for-test bypass mode for the memory to provide a write data signal; and
latching the write data signal in the read data latch responsive to a second binary value of the bypass signal during the design-for-test bypass mode for the memory.

Clause 15. The method of clause 14, further comprising:
latching the data in signal in a first flip-flop in the scan chain before latching the data in signal in the write data latch;
inverting an output signal from the read data latch to provide a data out signal; and
latching the data out signal in a second flip-flop in the scan chain.

Clause 16. A memory, comprising:
a write data latch;
a read data latch including a first logic gate having an input terminal for receiving a read data signal and having an output terminal for providing an output signal from the read data latch; and
a second logic gate configured to process a write data signal from the write data latch with a bypass signal for a design-for-test bypass mode for the memory, wherein the read data latch includes a third logic gate including an input terminal coupled to an output terminal of the second logic gate.

Clause 17. The memory of clause 16, wherein the first logic gate comprises a NAND gate and the second logic gate comprises a first AND gate, and wherein the read data latch further includes a second AND gate configured to AND a memory clock signal with output signal from the read data latch, and wherein the third logic gate comprises a NOR gate.

Clause 18. The memory of clause 16, further comprising:
an inverter having an input terminal coupled to the output terminal of the read data latch.

Clause 19. The memory of clause 16, wherein the first logic gate comprises a first NAND gate and the read data latch includes a second NAND gate that is cross coupled with the first NAND gate.

Clause 20. The memory of clause 19, wherein the second logic gate comprises a third NAND gate.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A memory, comprising:
a write data latch configured to latch a data in signal during a design-for-test bypass mode for the memory to provide a write data signal; and
a read data latch configured to latch a read data signal through a first input terminal during a read operation to the memory and to latch the write data signal through a second input terminal during the design-for-test bypass mode.

2. The memory of claim 1, further comprising:
a bitcell array; and
a memory periphery, wherein the memory periphery is configured to write the write data signal from the write data latch to the bitcell array during a write operation and to read the read data signal from the bitcell array during the read operation.

3. The memory of claim 1, further comprising:
a first inverter configured to invert an output signal from the read data latch to provide a data output signal.

4. The memory of claim 3, wherein the read data latch comprises:
a first logic gate having the first input terminal and having an output terminal configured to provide the output signal from the read data latch.

5. The memory of claim 4, wherein the first logic gate comprises a first NAND gate.

6. The memory of claim 4, further comprising:
a scan chain including a first flip-flop coupled to an input terminal of the write data latch and including a second flip-flop coupled to an output terminal of the first inverter.

7. The memory of claim 6, wherein the first flip-flop is coupled to the input terminal of the write data latch through a first combinational logic path, and wherein the second flip-flop is coupled to the output terminal of the first inverter through a second combinational logic path.

8. The memory of claim 5, further comprising:
a first AND gate configured to AND the write data signal with a bypass signal for the design-for-test bypass mode; and
a NOR gate configured to NOR an output signal of the first AND gate, wherein the first NAND gate is configured to NAND the read data signal with an output signal from the NOR gate.

9. The memory of claim 8, further comprising:
a second AND gate configured to AND an output signal from the read data latch with a memory clock signal, wherein the NOR gate is further configured to NOR the output signal from the first AND gate with an output signal from the second AND gate.

10. The memory of claim 5, further comprising:
a second NAND gate that is cross coupled with the first NAND gate.

11. The memory of claim 10, further comprising:
a third NAND gate configured to NAND a bypass signal for the design-for-test bypass mode with the write data signal, wherein the second NAND gate is a three-input NAND gate configured to NAND an output signal from the third NAND gate with a memory clock signal and with an output signal from the first NAND gate.

12. The memory of claim 11, further comprising:
a fourth NAND gate configured to NAND the bypass signal with an inverted version of the write data signal, wherein the first NAND gate is a three-input NAND gate configured to NAND an output signal from the second NAND gate with the read data signal and with an output signal from the fourth NAND gate.

13. The memory of claim 1, wherein the memory is incorporated into a cellular telephone.

14. A method of operation for a memory, comprising:
processing a read data signal through a first logic gate in a read data latch to provide a latched output signal at an output terminal of the first logic gate responsive to a first binary value of a bypass signal during a read operation to the memory;
latching a data in signal from a scan chain in a write data latch during a design-for-test bypass mode for the memory to provide a write data signal; and
latching the write data signal in the read data latch responsive to a second binary value of the bypass signal during the design-for-test bypass mode for the memory.

15. The method of claim 14, further comprising:
latching the data in signal in a first flip-flop in the scan chain before latching the data in signal in the write data latch;
inverting an output signal from the read data latch to provide a data out signal; and
latching the data out signal in a second flip-flop in the scan chain.

16. A memory, comprising:
a write data latch;
a read data latch including a first logic gate having an input terminal for receiving a read data signal and having an output terminal for providing an output signal from the read data latch; and
a second logic gate configured to process a write data signal from the write data latch with a bypass signal for a design-for-test bypass mode for the memory, wherein the read data latch includes a third logic gate including an input terminal coupled to an output terminal of the second logic gate.

17. The memory of claim 16, wherein the first logic gate comprises a NAND gate and the second logic gate comprises a first AND gate, and wherein the read data latch further includes a second AND gate configured to AND a memory clock signal with output signal from the read data latch, and wherein the third logic gate comprises a NOR gate.

18. The memory of claim 16, further comprising:
an inverter having an input terminal coupled to the output terminal of the read data latch.

19. The memory of claim 16, wherein the first logic gate comprises a first NAND gate and the read data latch includes a second NAND gate that is cross coupled with the first NAND gate.

20. The memory of claim 19, wherein the second logic gate comprises a third NAND gate.
